(19) United States
(12) Patent Application Publication
(10) Pub. No.: US 2026/0110075 A1
(43) Pub. Date: Apr. 23, 2026

(54) Evaporation boat with corrosion-resistant evaporation element

(71) Applicant: Kennametal Inc., Latrobe, PA (US)

(72) Inventor: Alexander Draken, Schongau (DE)

(21) Appl. No.: 19/058,656

(22) Filed: Feb. 20, 2025

(30) Foreign Application Priority Data
Feb. 23, 2024 (DE) 1020241051329

(51) Int. Cl. C23C 14/24; C23C 14/14

(52) U.S. Cl. CPC C23C 14/243; C23C 14/14

(57) ABSTRACT

An evaporation boat has an evaporation body consisting of an electrically conductive material, wherein the evaporation body comprises an evaporation element for evaporating metal fastened to the evaporation body such that an evaporation surface of the evaporation body is at least partially formed by the evaporation element. The evaporation element consists of a material that has a higher corrosion resistance to the metal to be evaporated than does the electrically conductive material of the evaporation body.

### RELATED APPLICATION DATA

The present application claims priority pursuant to 35 U.S.C. § 119(a) to German Patent Application Number 1020241051329 filed Feb. 23, 2024 which incorporated herein by reference in its entirety.

### FIELD

The invention relates to an evaporation boat having an evaporation body and an evaporation element fastened to the evaporation body for evaporating metal.

### BACKGROUND

So-called vacuum band metallization using PVD (physical vapor deposition) is a common method for coating flexible substrates with metals. The flexible substrate can be plastic film, metal foil, membranes or paper, for example. The most commonly used metal for coating substrates is aluminum. Substrates coated by means of PVD technology are widely used for packaging or decorative purposes. In addition to decorative purposes, the coating can in particular be used as surface protection or thermal insulation.

The evaporation of metals onto flexible substrates takes place in metallization systems. The substrate to be coated is passed over cooled rollers in the form of a long band, in the course of which the substrate is exposed to a metal vapor which is deposited on the substrate as a thin metal layer.

To generate the metal vapor, it is common to use evaporation boats. These are clamped between electrodes, for example made of copper, and heated by direct circuit continuity to temperatures of up to approximately 1700° C. A metal wire made of the metal to be evaporated is continuously guided onto the preheated evaporation boat and first liquefies on an evaporation surface of the evaporation boat as a molten mass and is then converted into the gas phase, thereby forming a metal vapor, and coats the flexible substrate. The entire metallization process takes place in a vacuum, typically in a vacuum chamber at a low pressure of approximately 10⁻⁴ mbar, which ensures controlled evaporation of the metal.

At the locations where the evaporation boat is in direct contact with the molten metal, the evaporation boat is subject to heavy corrosion that limits the tool life or service life of the evaporation boat. Typical evaporation boats are made of a ceramic material comprising titanium diboride (TiB₂) as an electrically conductive component and boron nitride (BN) as an electrically non-conductive component. The chemical reactions occurring in the course of corrosion affect boron nitride to a greater extent than titanium diboride, which changes the chemical composition with increasing service life of the evaporation boat towards a lower content of boron nitride, thereby decreasing the resistivity of the evaporation boat until further operation of the evaporation boat is no longer possible.

In order to be able to reliably ensure a constant vapor flow, evaporation boats therefore typically must to be replaced after about 15 to 18 operating hours, and the consumed evaporation boat must be disposed of. This is associated with high costs and waste levels.

### SUMMARY

The problem addressed by the invention is to provide an evaporation boat having a long service life, in particular an evaporation boat that is inexpensive to operate and that causes as little waste as possible.

The problem addressed by the invention is solved by an evaporation boat having an evaporation body consisting of an electrically conductive material, wherein the evaporation body comprises an evaporation element for evaporating metal fastened to the evaporation body such that an evaporation surface of the evaporation body is at least partially formed by the evaporation element. The evaporation element consists of a material that has a higher corrosion resistance to the metal to be evaporated than does the electrically conductive material of the evaporation body.

The invention is based on the principle of producing at least a portion of the evaporation surface of the evaporation body from a material different than the remaining evaporation body, having a higher corrosion resistance to the metal to be evaporated than does the material of the evaporation body. In this way, the extent and speed at which the evaporation body corrodes, even under operating conditions of the evaporation boat, can be limited so that the service life of the evaporation body increases. In other words, the location where the evaporation boat is exposed to the strongest corrosion is at least partially separated from the evaporation body. At the same time, the fastening between the evaporation body and the corrosion-resistant evaporation element ensures that the evaporation element is reliably secured to the evaporation body under the conditions prevailing during use of the evaporation boat. The fact that the evaporation body and the evaporation element are made of different materials also results in a high degree of flexibility in the design of the evaporation boat, so that an optimal adjustment to the intended operating conditions is enabled.

The metal to be evaporated is in particular aluminum, copper, silver, gold, zinc, or a combination thereof.

In one variant, the evaporation element is fastened to the evaporation body in a non-destructively releasable manner. In this way, the evaporation element can be replaced with a new evaporation element after a planned deployment period. Stated another way, after the planned deployment time, it is not necessary to dispose of and replace the entire evaporation boat, rather merely the evaporation element made from the corrosion resistant material, while the evaporation body can be reused. In this way, the amount of waste is reduced, and costs can be saved.

In this case, the planned deployment period of the evaporation element is in particular shorter than the service life of the evaporation body, so that the evaporation body can be used repeatedly with different evaporation elements before it must be disposed of.

Thus, while the evaporation element is made of a material that has a higher corrosion resistance than the electrically conductive material of the evaporation body, the evaporation element need not overall have a planned deployment period that is the same as or higher than the service life of the evaporation body. Rather, the planned deployment period is flexibly adjustable through the configuration of the evaporation element, for example, by the thickness of the evaporation element, the chemical composition of the evaporation element, and/or the proportion of the evaporation surface area of the evaporation body formed by the evaporation element.

To fasten the evaporation element to the evaporation body, the evaporation element can be fastened to the evaporation body in a positively locking manner. In this context, a positive lock is understood to mean that the relative movement between the evaporation element and the evaporation body is blocked or bounded at least in one spatial direction. By fastening the evaporation element in a positively locking manner to the evaporation body, a particularly simple mounting of the evaporation element on the evaporation body is possible. In particular, non-destructively releasable connections between the evaporation element and the evaporation body can be realized in a simple manner.

The evaporation body can comprise a receptacle, wherein the evaporation element is arranged at least partially, and in particular entirely, in the receptacle. The receptacle allows for a particularly simple mounting of the evaporation element on the evaporation body.

To produce a particularly reliable positive lock, the receptacle can have an undercut into which a protrusion of the evaporation element engages.

The receptacle can be laterally open in order to insert the evaporation element into the evaporation body while forming of a positive lock. This allows for easy assembly of the evaporation boat, a reliable fixation of the evaporation element on the evaporation body, and the ability to non-destructively separate the evaporation element from the evaporation body after its planned deployment period.

Furthermore, the receptacle can comprise a fastening opening that extends perpendicular to an extension plane of the receptacle, wherein the evaporation element engages into the fastening opening. In particular, the evaporation element has a fastening protrusion that engages into the fastening opening of the receptacle and, in this way, helps to fasten the evaporation element to the evaporation body.

The extension plane of the receptacle is in particular parallel to the evaporation surface of the evaporation body.

In one configuration, the fastening opening has a threading, and the evaporation element is screwed into the fastening opening. For example, the fastening protrusion of the evaporation element has a threading, which is designed as a counter-threading to the threading of the fastening opening and cooperates with it in order to fasten the evaporation element onto the evaporation body. It is understood that in this case, the evaporation element is not fastened to the evaporation body exclusively by way of a positive lock; additionally, a frictional lock is produced by the interplay of threading and counter-threading.

The receptacle of the evaporation body can be laterally bounded by boundary walls, wherein the evaporation element is inserted between the boundary walls. Stated another way, a positive lock results from the cooperation of the evaporation element within the receptacle and the boundary walls of the receptacle.

The evaporation element can be fastened to the evaporation body by means of fastening screws and/or fastening pins. In this case, the evaporation element has fastening receptacles that are complementary in particular to the fastening screws or pins, into which the fastening screws or pins are inserted. It is understood that the fastening screws and/or fastening pins can be separate components from the evaporation element, which are first inserted during assembly of the evaporation boat.

To protect the evaporation body particularly well against corrosion effects, at least 30% of the evaporation surface of the evaporation body can be formed by the evaporation element, preferably more than 50%, particularly preferably more than 80%. It is also possible for the entire evaporation surface of the evaporation body to be formed by the evaporation element.

The shape of the evaporation element is in principle not further limited, as long as the evaporation element can be fastened to the evaporation body such that the desired evaporation surface forms. For example, the evaporation element is a plate, or comprises a plate, that is received in the evaporation body or placed on it.

In one variant, the electrically conductive material of the evaporation body is a first ceramic material comprising titanium diboride and boron nitride. Corresponding ceramic materials are tested for use in evaporation boats. In addition, the desired electrical resistance of the evaporation body used for warming the evaporation body can be precisely adjusted via the weight fractions of titanium diboride and boron nitride in the first ceramic material.

In principle, the further composition of the first ceramic material is not further limited, as long as the respective material is fundamentally suitable for the operating conditions to which the evaporation boat is subjected.

The first ceramic material can be a two-component system consisting of titanium diboride and boron nitride, or it can include other components. For example, the first ceramic material can be a three-component system, in particular consisting of titanium diboride, boron nitride, and aluminum nitride, or a four-component system, in particular consisting of titanium diboride, boron nitride, aluminum nitride, and tungsten.

In a further variant, the electrically conductive material of the evaporation body is a carbon-containing material. For example, the carbon-containing material comprises graphite, or the evaporation body is comprised of graphite. An evaporation body made of carbon-containing material, in particular graphite, is much more cost-efficient to manufacture than an evaporation body made of a suitable ceramic material based on titanium diboride and boron nitride. Thus, even then, cost advantages are to be achieved when such evaporation bodies are only used once, i.e. without providing for an exchange of the plate fastened to the evaporation body. At the same time, the evaporation element which is separate from the evaporation body allows for the provision of a defined evaporation surface that can be heated to the temperature necessary to melt and evaporate the metal.

When an evaporation body of carbon-containing material is employed, the material of the evaporation element should be chosen in particular such that the evaporation element can be heated to a temperature sufficient to melt the metal to be evaporated through passive heating through the evaporation body.

In particular, when the evaporation body is made of a carbon-containing material, the evaporation body typically has a higher electrical conductivity than the evaporation element. Thus, the power applied in order to warm the evaporation boat flows entirely, or at least preferably, through the evaporation body rather than through the evaporation element, such that the evaporation element is not heated, or only to a comparatively small extent, through the current flow but through the evaporation body.

In particular, in the event that an evaporation body made from a carbon-containing material is used, at least 80% of the evaporation surface, and preferably the entire evaporation surface, is formed by the evaporation element.

The material of the evaporation element can be a second ceramic material comprising titanium diboride and/or boron nitride. To the extent that both the evaporation body and the evaporation element are made of a ceramic material consisting of titanium diboride and/or boron nitride, the ratio of titanium diboride to boron nitride in the second ceramic material is selected such that the evaporation element has the desired higher corrosion resistance to the metal being evaporated.

However, the further composition of the second ceramic material is also not fundamentally further limited, as long as the respective material is suitable for the operating conditions to which the evaporation boat is subjected and has a higher corrosion resistance than the evaporation body.

The first ceramic material can thus be a two-component system consisting of titanium diboride and boron nitride, analogous to the first ceramic material, or further components. For example, the second ceramic material can be a three-component system, in particular consisting of titanium diboride, boron nitride, and aluminum nitride, or a four-component system, in particular consisting of titanium diboride, boron nitride, aluminum nitride, and tungsten.

It is understood that, in the event that the electrically conductive material of the evaporation body is the first ceramic material and the material of the evaporation element is the second ceramic material, the first ceramic material and the second ceramic material will differ from one another, in particular chemically from one another.

In one variant, the second ceramic material comprises more than 50 weight percent titanium diboride, based on the total weight of the second ceramic material. In particular, the content of titanium diboride is in the range of greater than 50 to 80 weight percent, based on the total weight of the second ceramic material. At a content of 50 weight percent or less, the corrosion resistance of the evaporation element can be too low, while at a content of more than 80 weight percent, the electrical resistance of the evaporation element can be too low to operate an evaporation boat with the evaporation element in conventional evaporation systems. In addition, the hardness of the second ceramic material increases with increasing content of titanium diboride, which increases the effort required to process the second ceramic material at a content of more than 80 weight percent.

In this variant, the second ceramic material can also comprise less than 50 weight percent boron nitride, based on the total weight of the second ceramic material, for example 20 weight percent to less than 50 weight percent.

In another variant, the second ceramic material consists of boron nitride. In this variant, the evaporation element is made entirely of an electrically non-conductive material, such that the evaporation element cannot be actively resistance-heated by a current flow passing through the evaporation element, but must be brought to the temperature necessary for evaporating the metal by the evaporation body that is in contact with the evaporation element. However, the proportion of boron nitride in this variant is maximized, so that the evaporation element can have a maximized planned deployment period, despite corrosion reactions, before the boron nitride is consumed by corrosion effects.

### BRIEF DESCRIPTION OF THE DRAWINGS

Further features and properties arise from the following description of exemplary embodiments and examples, which should not be understood in a restrictive sense, as well as from the drawings. The figures show:

FIG. 1 a perspective view of a first embodiment of an evaporation boat according to the invention,

FIG. 2 a cross-sectional view along the line A-A of FIG. 1,

FIG. 3A a view of a second embodiment of the evaporation boat according to the invention,

FIG. 3B a view of a modification of the evaporation boat of FIG. 3A,

FIG. 4 a cross-sectional view along the line B-B of FIG. 3A or FIG. 3B,

FIG. 5 a view of an evaporation body of a third embodiment of the evaporation boat according to the invention,

FIG. 6 a cross-sectional view along the line C-C of FIG. 5,

FIG. 7 an enlarged view of the detail D from FIG. 6,

FIG. 8 a side view of a corrosion-resistant evaporation element that can be fastened to the evaporation body of FIG. 5 for forming the evaporation boat according to the invention,

FIG. 9 a side view of an alternative variant of the evaporation element of FIG. 8,

FIG. 10 a perspective view of an evaporation body of a fourth embodiment of the evaporation boat according to the present invention,

FIG. 11 a side view of the evaporation body of FIG. 10,

FIG. 12 an enlarged view of the detail E from FIG. 11,

FIG. 13 a view of a corrosion-resistant evaporation element that can be fastened to the evaporation body of FIG. 10 for forming the evaporation boat according to the invention,

FIG. 14 a side view of the plate from FIG. 13,

FIG. 15 an enlarged view of the detail F from FIG. 14.

### DETAILED DESCRIPTION

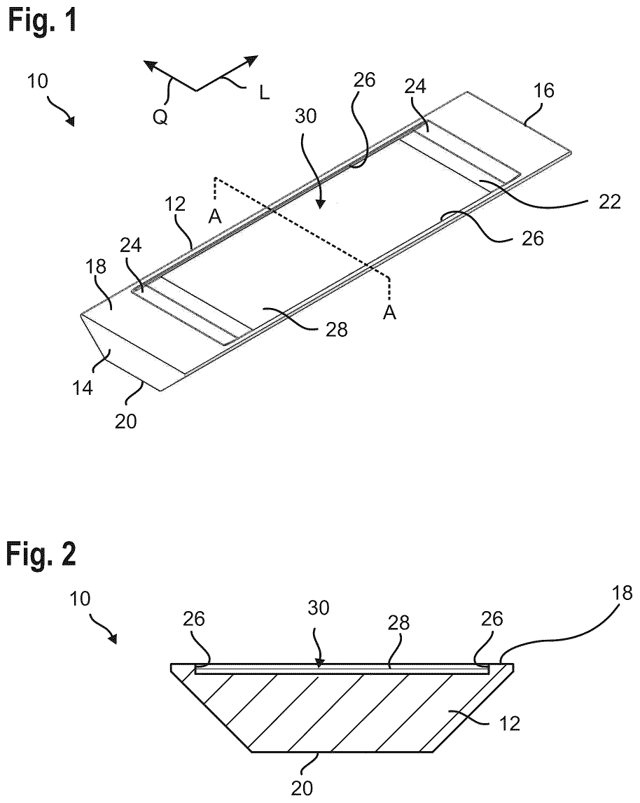

FIG. 1 shows a first embodiment of an evaporation boat 10 according to the present invention.

The evaporation boat 10 has an evaporation body 12 extending from a first lateral surface 14 to a second lateral surface 16 opposite the first lateral surface 14 along a longitudinal direction L of the evaporation boat 10.

In the embodiment shown, the first lateral surface 14 and the second lateral surface 16, and thus the cross-section of the evaporation body 12, are trapezoidal.

The evaporation body 12 further comprises a top side 18 and a bottom side 20 opposite the top side 18.

On the top side 18, the evaporation body 12 has a receptacle 22, which is configured as a recess in the evaporation body 12 and is bounded by oblique connection surfaces 24 in the direction of the first lateral surface 14 and the second lateral surface 16, i.e. in the longitudinal direction L.

In a transverse direction Q, which is perpendicular to the longitudinal direction L, the receptacle 22 is bounded by boundary walls 26 of the evaporation body 12.

The evaporation body 12 with the receptacle 22 can be obtained by first producing an evaporation body precursor whose top side extends in a planar manner from the first lateral surface to the second lateral surface and in which the receptacle 22 is introduced by a subsequent machining step while obtaining the evaporation body 12, for example by milling.

However, other manufacturing variants are also contemplated, for example by sintering an evaporation body green part, which already has a design that is complementary to the receptacle 22.

The evaporation body 12 is made of an electrically conductive material, for example a first ceramic material comprising titanium diboride as an electrically conductive component and boron nitride as an electrically non-conductive component.

Within the receptacle 22, an evaporation element 28 is received, which is formed as a plate that is held between the boundary walls 26, such that the evaporation element 28 is fastened to the evaporation body 12 in a positively locking manner, namely in the receptacle 22.

Stated another way, the evaporation element 28 can be inserted or pushed into the receptacle 22 of the evaporation body 12 in order to obtain the evaporation boat 10.

In the embodiment shown, the evaporation element 28 covers the receptacle 22 nearly entirely, so that only those regions of the receptacle 22 of the evaporation body 12 located between the evaporation element 28 and the respective connection surfaces 24 are directly accessible.

It is understood that the evaporation element 28 can also cover a smaller or larger proportion of the receptacle 22 than is shown in FIG. 1.

FIG. 2 shows a cross-section through the evaporation boat 10 along the plane A-A from FIG. 1.

It can be better seen in FIG. 2 that the evaporation element 28 abuts the boundary walls 26 in order to fasten the evaporation element 28 to the evaporation body 12 in a positively locking manner.

Within the receptacle 22, there is an evaporation surface 30 of the evaporation body 12, which is formed by the surface of the evaporation element 28 facing toward the top side 18 of the evaporation body 12 and the regions of the receptacle 22 not covered by the evaporation element 28.

During the operation of the evaporation boat 10, as is known to the person skilled in the art, the evaporation surface 30 is heated to a temperature sufficient to melt a metal wire (not shown) that is guided onto the evaporation surface 30 and evaporate the molten metal. The metal is, in particular, aluminum.

The evaporation element 28 consists of a material that has a higher corrosion resistance to the metal to be evaporated than does the electrically conductive material of the evaporation body 12. Thus, even during operation of the evaporation boat 10, the evaporation body 12 no longer comes into contact with the molten metal, or only at a reduced level, which can limit corrosion effects of the evaporation body 12 and increase the service life of the evaporation body 12.

The evaporation element 28, on the other hand, is merely fastened within the receptacle 22 in a positively locking manner and is in particular connected to the evaporation body 12 in a non-destructively releasable manner. Accordingly, the evaporation element 28 is interchangeable, i.e. it can be removed after a planned deployment period, which is usually shorter than the service life of the evaporation body 12, and replaced with a new evaporation element 28.

For example, the evaporation element 28 is made of a second ceramic material that comprises titanium diboride and/or boron nitride analogously to the evaporation body 12. However, in order to achieve a higher corrosion resistance, the second ceramic material can have a higher content of titanium diboride than the first ceramic material.

The first ceramic material and the second ceramic material can each be a two-component system of titanium diboride and boron nitride, a three-component system of titanium diboride, boron nitride, and aluminum nitride, or a four-component system of titanium diboride, boron nitride, aluminum nitride, and tungsten, wherein the first ceramic material and the second ceramic material differ from one another.

In principle, other combinations of materials are contemplated. For example, it is possible for the evaporation body 12 to consist of a carbon-containing material, for example graphite, while the evaporation element 28 consists of a ceramic material corresponding to, for example, the previously described first ceramic material or the second ceramic material. In such a combination, the evaporation body 12 itself is comparatively inexpensive to manufacture, so that the service life of the evaporation body 12 can also correspond to the planned deployment period of the evaporation element 28.

In such a case, in particular, it is also possible that the evaporation element 28 is not connected to the evaporation body 12 in a non-destructively releasable manner.

In the following, further embodiments of the evaporation boat 10 according to the invention are described, which substantially correspond to the first embodiment, so that only differences will be discussed. Identical reference numerals denote like or functionally like components, and properties and features described for one embodiment also apply to the other embodiments, unless this is explicitly excluded or technically impossible.

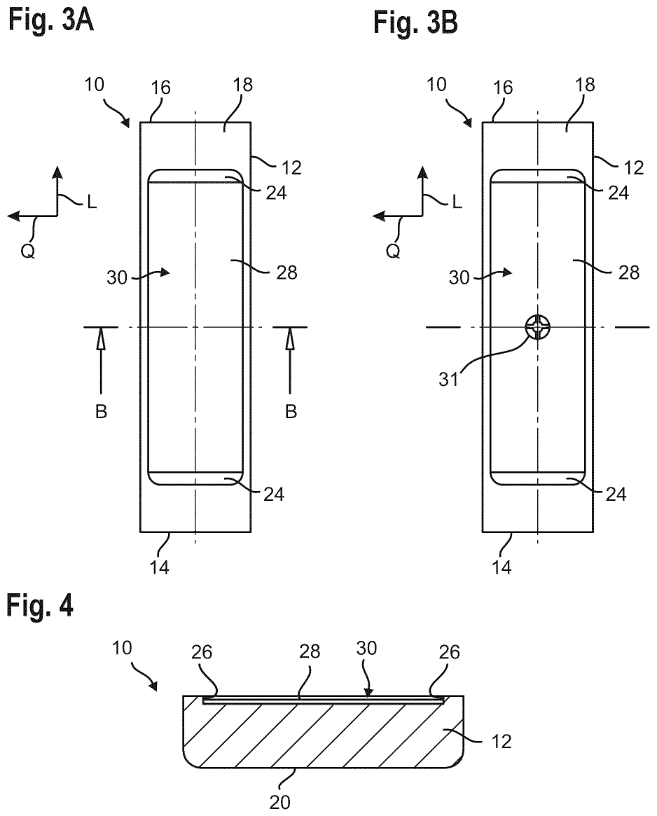

FIG. 3A shows a view of a second embodiment of the evaporation boat 10 according to the invention.

In the second embodiment, the evaporation element 28 covers the entire receptacle 22, apart from the obliquely extending connection surfaces 24.

Further, the receptacle in the plane L-Q has a rounded, rectangular cross-section and the evaporation body 12 has a substantially rectangular cross-section perpendicular to the plane L-Q, which is rounded at the edges facing the bottom side 20, as can be seen in the cross-sectional view according to FIG. 4.

FIG. 3B shows a modification of the second embodiment of the evaporation boat 10 of FIG. 3A.

In the modification according to FIG. 3B, the evaporation element 28 has a fastening opening into which a fastening screw 31 is inserted in order to fasten the evaporation element 28 in the receptacle 22, in addition to the positive lock via the boundary walls 26.

The fastening screw 31 extends through the evaporation element 28 and into the evaporation body 12. In order to fasten the fastening screw 31, the fastening opening and/or the receptacle of the evaporation body 12 can comprise a counter-threading corresponding to a threading of the fastening screw 31.

The insertion of a fastening screw 31 is particularly advantageous when the evaporation element 28 is subjected to thermal delay under operating conditions of the evaporation boat, for example, when it bulges upwardly away from the receptacle 22. In this case, such a thermal delay is prevented by the fastening screw 31.

In principle, it is also possible for a plurality of fastening screws 31 to be provided or that fastening pins are used instead of fastening screws 31.

It is understood that the fastening screw 31 is made of a material that resists the metal to be evaporated on the evaporation surface 30, analogously to the evaporation element 28.

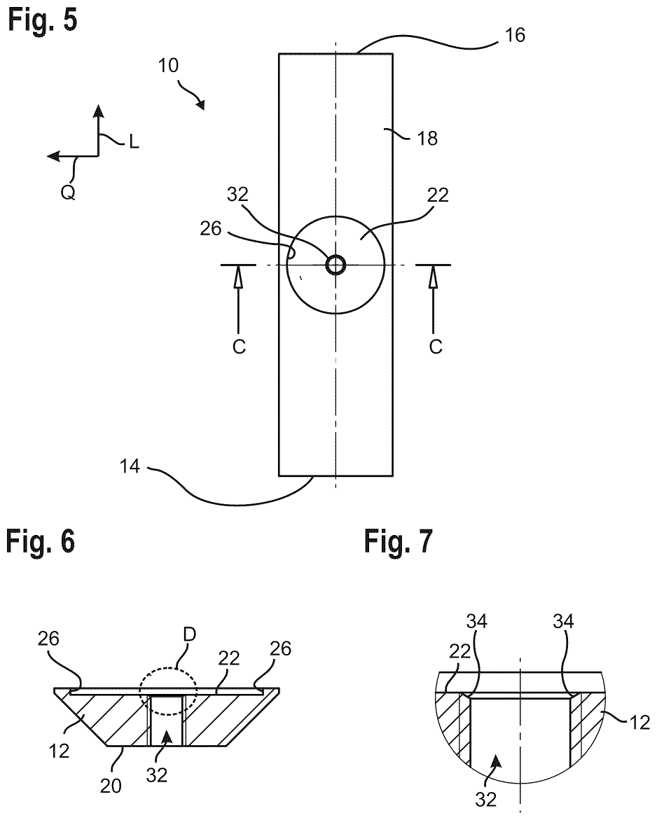

FIG. 5 shows a view of an evaporation body 12 of a third embodiment of the evaporation boat 10 according to the invention.

In the third embodiment, the receptacle 22 in the plane L-Q has a circular cross-section, wherein the center of the receptacle 22 coincides with a center point of the evaporation body 12 along the longitudinal direction L and the transverse direction Q.

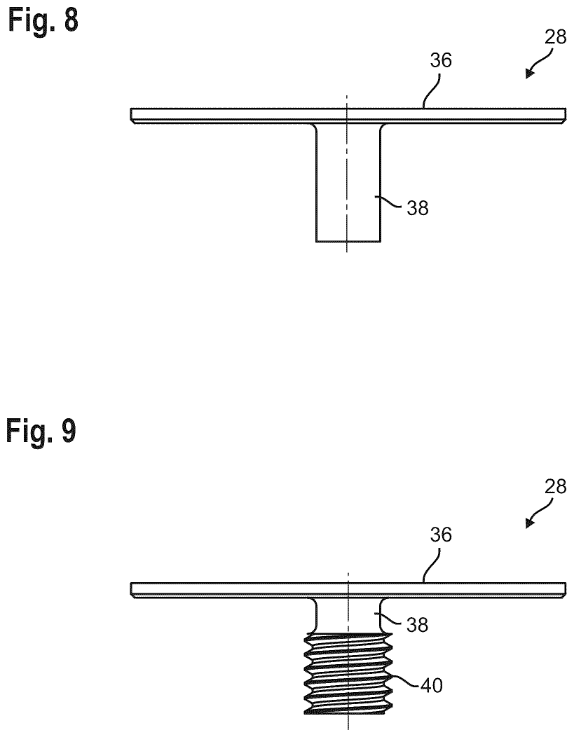

Also in the third embodiment, the receptacle 22 is bounded by boundary walls 26, so that the evaporation element 28 (cf. FIG. 8) can be fastened in the receptacle 22 in a positively locking manner.

Furthermore, the receptacle 22 has a fastening opening 32 extending perpendicular to the plane L-Q through the evaporation body 12 towards the bottom side 20 of the evaporation body 12, as shown in the cross-sectional view in FIG. 6.

FIG. 7 shows the detail D of FIG. 6 in an enlarged view, in which it can be better seen that the fastening opening 32 is connected to the receiving plane of the receptacle 22 via a collar section 34.

FIG. 8 shows a side view of the connection element 28 as can be deployed in an evaporation boat having an evaporation body 12 according to FIG. 5.

The evaporation element 28 in this embodiment comprises a plate 36 and a fastening protrusion 38 that extends perpendicular to the plane of the plate 36 and is formed so as to be complementary to the fastening opening 32 of the evaporation body 12.

To assemble the evaporation element 28, the fastening protrusion 38 is inserted into the fastening opening 32 of the receptacle 22 until the plate 36 comes to rest in the receptacle 22 and is thus fastened to the evaporation body 12 in a positively locking manner.

FIG. 9 shows an alternative variant of the evaporation element 28 in which the fastening protrusion 38 is equipped with a counter-threading 40. If such an evaporation element 28 is to be deployed, the fastening opening 32 of the evaporation body 12 comprises a threading (not shown) corresponding to the counter-threading 40, so that the evaporation element 28 can be screwed into the evaporation body 12. In this case, the evaporation element 28 is fastened to the evaporation body 12 in a frictionally locking manner in addition to the positive lock between the plate 36 and the boundary walls 26.

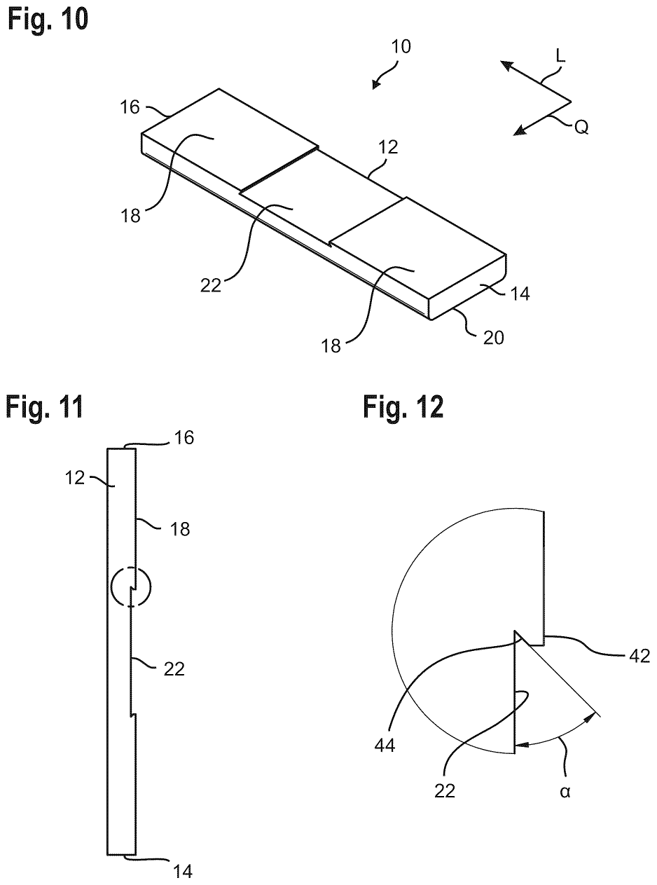

FIG. 10 shows a perspective view of an evaporation body 12 of a fourth embodiment of the evaporation boat 10 according to the present invention.

In the fourth embodiment, the receptacle 22 is not bounded by boundary walls 26 in the transverse direction Q, so that the evaporation element 28 can be pushed laterally into the receptacle 22.

To fasten the evaporation element 28 in the receptacle 22, a protrusion 42 is provided at ends of the receptacle 22 that opposite one another in the longitudinal direction L, which is shaped such that the receptacle 22 has a wedge-shaped fastening groove 44 with an opening angle a that provides an undercut.

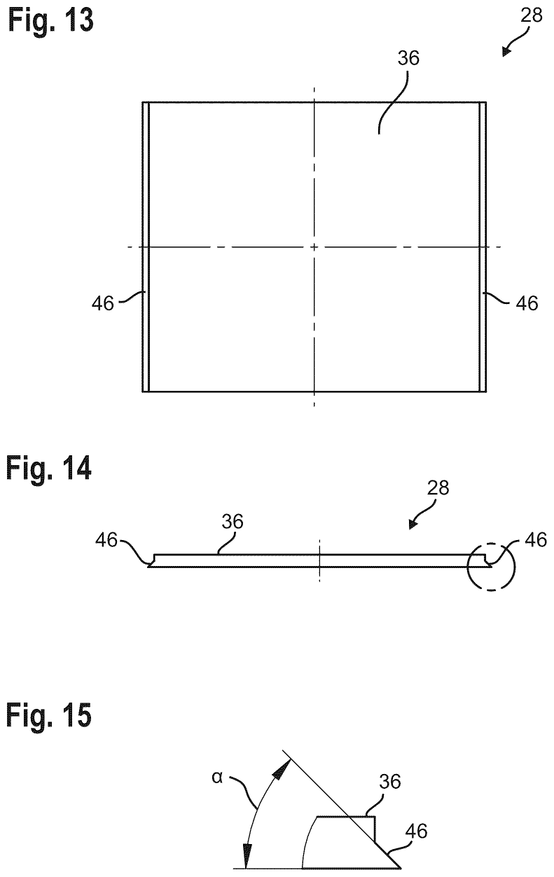

FIG. 13 shows a view of the evaporation element 28 as can be deployed in the evaporation body 12 according to FIG. 10.

The evaporation element 28 in this embodiment is a plate 36 having a respective protrusion 46 at opposite ends. As shown in FIG. 14, and in particular in the illustration according to FIG. 15, the protrusion 46 is designed so as to complement the fastening groove 44 of the evaporation body 12, so that the evaporation element 28 can be pushed into the evaporation body 12 laterally into the receptacle 22, such that an evaporation surface 30 is formed from the top side 18 of the evaporation body 12 and the top side of the plate 36.

As soon as the planned deployment period of the plate 36, i.e. the evaporation element 28, has been achieved, it can be removed from the evaporation body 12 in a non-destructive manner and exchanged for a new plate 36.

In the configuration shown in FIG. 10, the receptacle 22 is opened laterally in the direction of the transverse direction Q. Of course, it is also possible for the receptacle 22 to be opened laterally in the direction of the longitudinal direction L, so that the plate 36 can be inserted and removed starting from the first lateral surface 14 or the second lateral surface 16.

Furthermore, in the variant according to FIG. 10, the fastening groove 44 is configured so as to extend substantially parallel to the receiving plane of the receptacle 22. Of course, alternative configurations of the fastening groove 44 are also contemplated, in which the fastening groove 44 has a different orientation relative to the receiving plane of the receptacle 22, for example perpendicular to the receiving plane.

Overall, the evaporation boat 10 according to the invention is characterized by a high flexibility in the design of evaporation body 12 and evaporation element 28 as well as a long service life of the evaporation body 12. In addition, during the operation of the evaporation boat 10 according to the invention, there are low amounts of waste or at least low amounts of waste of ceramic materials.

1. An evaporation boat having an evaporation body made from an electrically conductive material,
wherein the evaporation body comprises an evaporation element for evaporating metal fastened to the evaporation body such that an evaporation surface of the evaporation body is at least partially formed by the evaporation element, and
wherein the evaporation element consists of a material that has a higher corrosion resistance to the metal to be evaporated than does the electrically conductive material of the evaporation body.

2. The evaporation boat according to claim 1, wherein the evaporation element is fastened to the evaporation body in a non-destructively releasable manner.

3. The evaporation boat according to claim 1, wherein the evaporation element is fastened to the evaporation body in a positively locking manner.

4. The evaporation boat according to claim 1, wherein the evaporation body comprises a receptacle, and wherein the evaporation element is arranged at least partially in the receptacle.

5. The evaporation boat according to claim 4, wherein the receptacle comprises an undercut into which a protrusion of the evaporation element engages.

6. The evaporation boat according to claim 4, wherein the receptacle comprises a fastening opening that extends perpendicular to a receiving plane of the receptacle, and wherein the evaporation element engages into the fastening opening.

7. The evaporation boat according to claim 6, wherein the fastening opening comprises a threading, and the evaporation element is screwed into the fastening opening.

8. The evaporation boat according to claim 4, wherein the receptacle is laterally bounded by boundary walls, and wherein the evaporation element is inserted between the boundary walls.

9. The evaporation boat according to claim 1, wherein the evaporation element is fastened to the evaporation body by means of fastening screws and/or fastening pins.

10. The evaporation boat according to claim 1, wherein at least 30% of the evaporation surface of the evaporation body is formed by the evaporation element.

11. The evaporation boat according to claim 1, wherein the electrically conductive material of the evaporation body is a first ceramic material comprising titanium diboride and boron nitride.

12. The evaporation boat according to claim 1, wherein the electrically conductive material of the evaporation body is a carbon-containing material.

13. The evaporation boat according to claim 1, wherein the material of the evaporation element is a second ceramic material comprising titanium diboride and/or boron nitride.

14. The evaporation boat according to claim 13, wherein the second ceramic material consists of more than 50 wt. % titanium diboride, based on the total weight of the second ceramic material.

15. The evaporation boat according to claim 13, wherein the second ceramic material consists of boron nitride.
